(19) United States
(12) Patent Application Publication
(10) Pub. No.: US 2024/0003979 A1
(43) Pub. Date: Jan. 4, 2024

(54) NEURAL NETWORK-BASED MONITORING OF COMPONENTS AND SUBSYSTEMS FOR BATTERY-ENABLED DEVICES

(71) Applicant: John Olson, Boulder, CO (US)

(72) Inventor: John Olson, Boulder, CO (US)

(21) Appl. No.: 18/217,297

(22) Filed: Jun. 30, 2023

Related U.S. Application Data
(63) Continuation-in-part of application No. 17/952,473, filed on Sep. 26, 2022.
(60) Provisional application No. 63/357,416, filed on Jun. 30, 2022.

(51) Int. Cl. G01R 31/367; G06N 3/02; G01R 31/36; G01R 31/392; G01R 31/387; G01R 31/389

(52) U.S. Cl. CPC G01R 31/367; G06N 3/02; G01R 31/3648; G01R 31/392; G01R 31/387; G01R 31/389

(57) ABSTRACT

A neural network model is in communication with a energy storage device sensor that monitors, evaluates, and determines an operating condition and/or life expectancy of one or more electrical or mechanical subsystems of an energy storage device, such as a battery, and an associated device. A battery sensor includes a microcontroller that processes information from the neural network model and evaluates the battery subsystem operation to determine component status and generate an output indicative of one of component state of health or subsystem operation.

### CROSS-REFERENCE TO RELATED APPLICATIONS

This application is a continuation-in-part patent application of U.S. patent application Ser. No. 17/952,473, filed Sep. 26, 2022 and further claims the benefit of U.S. Provisional Application No. 63/357,416, filed Jun. 30, 2022, the disclosures of which are incorporated herein by reference in their entirety.

### BACKGROUND OF THE INVENTION

This invention relates in general to battery state monitoring of a battery having any chemistry construction, size, and pack voltage. One such exemplary application of a battery state monitor is for manual and/or power-driven personal mobility vehicles. In particular, the battery state monitoring system can determine the operating condition and life expectancy of electronically-connected components and subsystems of any battery powered device such as, for example, a power-driven personal mobility vehicle.

Power-driven personal mobility vehicles include power wheelchairs, manual wheelchairs with add-on propulsion units and/or electrical subsystems, manually propelled wheelchairs, and scooters designed to aid mobility of disabled users. The power-driven personal mobility vehicles and manual wheelchairs with related power systems use electric motors and other electrical sub-systems to propel the vehicle. Power-driven personal mobility vehicles designed for disabled users may be the user's primary or only source of mobility in certain instances. If the wheelchair becomes inoperable because of an electrical sub-system failure the user is stranded. For these users, loss of operation equals loss of freedom.

Despite the potential loss of personal freedom, most users of power-driven personal mobility vehicles are not made aware of looming sub-system failures. A failure can become a crisis that is exacerbated by accompanied high costs for repair or replacement. In addition, the battery of the power wheelchair are subject to aging and loss of performance. What is needed is a health prediction method and associated system for the battery that will allow for pro-active maintenance and repair.

Closely related is the ability of the battery to power the personal mobility vehicles. Although not a battery failure, when the battery is at the end of discharge the user could also be stranded and experience a loss of personal freedom. For example, conventional methods to measure battery capacity typically rely on simple battery terminal measurements, such as terminal voltage, to estimate a state of charge or charge level. This measurement does not accurately reflect a battery's ability to provide a sufficient voltage and current output to operate a wheelchair. What is also needed is a method to monitor available battery parameters and generate an accurate prediction of a battery's state of charge.

Neural network models are well-known in the prior art and considered mature in their current state of development. Neural networks were one of the first artificial intelligence methods developed and intended to emulate the brain by using interconnected nodes as shown in FIG. 2. They require no theory or existing model for use, but knowledge of the system is important to allow proper selection of input data. The neural network models are created using training input data. Ideally, the training input data sets are selected so as to represent all of the possible (or likely) operating states of the system over life. When training the neural network, the training data set includes the outputs (the answers). After training, the neural networks operate by calculating the output (answer) using independent real-time measurement of input data.

A great deal of effort has been devoted to developing neural network modeling technology, their architectures, and how to best solve them; and this work has matured significantly. These models are a highly developed mathematical tool that enable the monitoring of batteries for wear and failure. Neural network modeling software is available commercially, either discretely or as part of a larger mathematical software packages (e.g., Matlab). This invention relates to using the powerful capabilities of neural network models for accurately predicting the state of health of electrical subsystems, for example in power-driven personal mobility vehicles such as power-driven or manual wheelchairs. The invention further provides for the monitoring of electrical sub-systems and assessment of their state of continued operability. As web-enabled connection of devices becomes more prevalent, one consideration of connected or monitored batteries over the internet is to relay important state information including: state of charge (SOC) and state of health (SOH) and availability for its use. The state of charge acts as a fuel gauge for the discharge or charge process. The state of health relates to the battery's ability to store electrical energy and release it as compared to its newly manufactured ability.

While monitoring and communicating battery condition through web-enabled devices is becoming practical, many examples of hardware developed for internet communication involve microcontrollers having varied methods to transfer data to the internet. Many different methods to transfer the data are possible, including but not limited to: Wi-Fi, Bluetooth, GSM and other cellular phone based methods (e.g., 3G, 4G, 5G, etc.), Ethernet cables, dial-up with a computer modem via telephone circuits, broadband over coaxial cable, fiber optics, or copper wires, and satellite communications. These are typically integrated devices with both the microcontroller and data transmission functionality included. However, the battery data collection is not often considered and is not related to the method and hardware used for data transmission. Much less attention has also been given to the actual data required for transmission. Current systems are configured to transfer all the raw data to the internet and perform calculations remotely, such as through cloud-based processing. Because of the large volume of data transmitted, then multiplied by the number of devices requiring monitoring, available bandwidth limitations and transmission costs greatly impact monitoring capabilities.

For battery state monitoring, determination of state of charge is equivalent to a battery fuel gauge. When the battery is fully charged, it is at 100% state of charge and when fully discharged it is at 0% state of charge. Many methods exist to determine the battery state of charge, but they all have shortcomings or inaccuracies. For example, the state of the art method for determination of SOC involves current integration or amp-hour (Ah) counting. The SOC is determined from the ratio of Ah discharged to the total Ah capacity of the battery. While this method is accurate when the battery new, over life the total Ah capacity of the battery decreases due to degradation. Most Ah counting techniques do not adjust for the changing total Ah capacity, and thus errors as large as 50% or more are possible by end of life. One familiar context is the battery “fuel gauge” of cell phones, where most are familiar with the problems but few understand the cause. When a battery is new, the phone SOC indicator faithfully reports SOC from 100% to 0%, and when the indicator is near 0% the phone will shut off. However, when the battery has aged it has lower capacity. The initial SOC indicator will act like it is tracking SOC starting with 100% and declining with use. However, the user then finds the phone shutting down when the SOC indicator still shows remaining capacity (e.g., 50%). This is due to the loss of total Ah capacity in the battery. This battery would have lost 50% of its original capacity.

Determination of state of health (SOH) is similar to SOC, being a state measurement from 100% to 0%. It indicates the age or health of the battery which is 100% when new and 0% when it fails. Few methods exist to quantify the SOH of a battery, and those that do exist suffer from inaccuracies. The devices that exist to monitor SOC and SOH for batteries typically require additional hardware for large batteries to measure the high currents that flow (often in the 100's of amperes). They also rely on the monitored battery to provide power for the sensor/monitor. Although this energy draw seems modest compared to the amount of energy stored in a large battery, over seasonal time periods this relatively small discharge can completely discharge the battery. In applications where battery monitors have integrated displays to convey battery data or state information (e.g., SOC and SOH) to the user, location of the battery may make accessing the display difficult. In addition, some types of large batteries, in particular flooded lead-acid batteries, have accessible cells with water filling caps that also allow small amounts of sulfuric acid mist to escape from the battery. Over time the tops of the batteries, terminals, and connection lugs can have films of sulfuric acid that results in corrosion and degradation of these components. Battery sensors connected to the battery are also exposed to this acid and can suffer from the same degradation.

To address the above limitations of current battery sensing and monitoring devices, what is needed is a high-current capable sensor/monitor that is installable without requiring system modification, limits parasitic power consumption and is responsive to inactivity periods, capable of remote display orientations, and resistant to deleterious environmental conditions. In addition, a desirable feature of a battery sensing and monitoring device is to collect and process raw data locally and transmit post-processing results to a wide variety of microcontroller and data transmission devices of various types.

### SUMMARY OF THE INVENTION

This invention relates to the field of batteries, generally of any chemistry, size or pack voltage, and in particular to a battery sensor configured to monitor a battery state including, but not limited to, state of charge (SOC) and state of health (SOH). By performing battery state calculations in the battery sensor, the amount of data for transmission can be reduced by a factor of over 10,000 with no loss of information. In one particular embodiment, the battery sensor is configured for typically larger batteries of 12V to 48V and >10 Ah capacity and packs. It can be used with any rechargeable (secondary) battery type including but not limited to: lead-acid batteries (flooded, sealed, low maintenance, AGM, Gel), lithium-ion batteries (mixed metal oxide or iron phosphate), nickel metal hydride batteries and nickel hydrogen batteries. Each battery type has a distinct model for SOC and SOH. The Battery Sensor is enabled with a communications module to permit web-based transmission of processed data to report SOC and/or SOH.

This invention also relates to methods and systems for determining the operating condition including but not limited to state of health of one or more electrical or mechanical systems of a personal mobility vehicle, such as a power-driven wheelchair or a manually operated wheelchair. Although a set of embodiments is described in the context of a power-driven wheelchair, the methods and systems disclosed herein are applicable to any battery powered device, whether mobility-based, consumer-based, automotive-based, military based or industrial-based devices. To function, any complex, battery-powered system, such as a power-driven personal mobility vehicle, uses multiple common electrical subsystems that are subject to wear and failure. These subsystems may include, but are not limited to, power drive motors, linear actuator motors, joystick and user input interface devices, batteries and battery chargers, electro-mechanical brakes and wiring harnesses, structural members, bearings, interface elements, and connectors. The operating condition and life expectancy may be determined by considering an individual electrical or mechanical system, and/or by considering the interactions of any of the foregoing electrical or mechanical systems with one other.

Neural network models are well-known for their use in systems that generate large amounts of data such as machine vision. However, their ability to form models from multiple input data allow them to be applied to any variety of calculation problems, including calculation of the state of health of an electrical sub-system of a power-driven personal mobility vehicle. In order to create a useful neural network model it is necessary to use input data that reflect the aging (wear) of the sub-system. For example, the electrical resistance of motor brushes is known to increase as the brushes age. After the model is created, it is not modified or re-trained in actual operation, it exists as a static model. In operation, the calculated input data to the static neural network model in order to calculate the current state of health of the batteries or other electrical subsystems.

In some embodiments, a method of assessing an operational state of health for one or more electrical subsystems comprises gathering input data from the one or more subsystems by using a plurality of sensors operatively coupled to a neural network model by a microcontroller. The neural network model processes the received input data to determine a calculated result or output for the one or more subsystems. The microcontroller can store the result in a computer-readable storage medium or transmit the digital result (output) data in any number of known ways common in the art. According to some embodiments, the plurality of sensors includes, but is not limited to, one or more voltage sensors, one or more current sensors, and one or more temperature sensors. In some cases, the sensor derived data is used directly as raw input data for the models. In other cases, other input data are derived from the sensor data.

In certain embodiments, the microcontroller may have the capabilities of both a computer and a data acquisition system. It can have computer memory that holds the machine program that allows the system to function along with the neural network models and the capability to perform the necessary system monitoring calculations. In certain embodiments, the microcontroller functions to gather input data from the plurality of sensors, perform calculations on these input data, calculate additional derived input data, if needed, and then uses the neural network models to calculate the output results of state of health. The microcontroller may also provide additional input data in the form of a time base that can be used directly as input data or used to calculate other derived input data.

According to some embodiments, the calculated result relates to a specific subsystem state of health of a singular component such as a battery, a battery charger, a drive motor, an actuator motor, electro-mechanical parking brakes, or a wiring harness and connectors.

According to some embodiments, the calculated result comprises a range of values for a component state of health between 0 and 100 percent.

According to some embodiments, the microcontroller measures operation of the one or more power wheelchair electrical subsystems by accepting one or more inputs from voltage sensors, current sensors and temperature sensors.

In some embodiments, a power-driven personal mobility vehicle comprises at least one battery; at least one drive motor; and a microcontroller operatively coupled to a plurality of sensors and configured to measure at least voltage, current, and temperature input data associated with the at least one battery. The microcontroller uses the neural network model to determine at least one of a state of charge or a state of health of the at least one battery.

According to some embodiments, the neural network model is created from a training input data set. The neural network model is designed to use the raw input data and other derived input data from operation of at least one electrical subsystem of the power personal mobility vehicle. In some embodiments, a system for assessing an operational state of health for one or more subsystems of a power-driven personal mobility vehicle comprises a plurality of sensors operatively coupled to neural network models by a microcontroller, the plurality of sensors configured for monitoring the one or more subsystems, the neural network model configured for calculating state of health from the input data from the plurality of sensors.

A separate neural network model may be created for each electrical subsystem in the wheelchair and may be independent from the other models. The neural network models are created using training input data obtained from a variety of means including, but not limited to laboratory testing, field testing, or data created by calculations. The training input data is configured to reflect the wear over time of the electrical subsystem to be monitored.

In some embodiments, a system is provided for assessing a state of charge for a battery comprising one or more battery modules. The state of charge of the battery reflects the charge of the battery from full charge (100% state of charge) to fully discharged (0% state of charge). The system comprises one or more battery voltage sensors operatively coupled to a neural network model by a microcontroller; one or more battery current sensors operatively coupled to the neural network model by a microcontroller; and one or more battery temperature sensors operatively coupled to the neural network model by a microcontroller. According to some embodiments, a battery temperature sensor operatively coupled to the neural network model by a microcontroller is indicative of a temperature measured on or near the outer case of the battery being used.

In one embodiment, the power-driven personal mobility vehicle is a powered wheelchair, and the battery power source is a lead acid battery. In other embodiments, the battery may be any primary or secondary battery, including but not limited to a lithium-ion battery, a nickel metal hydride battery, or a nickel cadmium battery. In certain embodiments, the sensor according to the invention is broadly configured as a energy storage device output monitor. While embodiments are described in conjunction with operation of a battery, generally as described below, the invention may also include other energy storage devices, such as but not limited to capacitors (including ultra capacitors an/or supercapacitors) and fuel cells. The powered wheelchair includes a microcontroller configured to measure designated parameters associated with battery charge level and battery health, and to output a status indicator of the battery state of health and state of charge.

In some embodiments, the components and subsystems of the power-driven personal mobility vehicle are monitored by the neural network model. Other powered wheelchair sub-systems that can be monitored for state of health include: actuator motors, electro-mechanical brakes, the battery, the battery charger and wiring harnesses and connectors.

In some embodiments, the power-driven personal mobility vehicle is configured to include a microcontroller. The microcontroller implements neural network models of the electrical subsystems of the vehicle. The microcontroller measures voltage and current at the battery terminals, over time; along with the temperature of the electrical subsystem over the same time basis as raw inputs to the neural network model. The microcontroller also calculates derived input data using various mathematical combinations of the raw input data. For example, the battery voltage divided by the current flow through the battery results in the resistance of the battery. The resistance of the battery in used as a derived input data for the associated neural network model.

In some embodiments, the output of the neural network models can be monitored remotely through a display device and/or an internet-based monitoring application. The data output can be transferred to the internet by any of a variety of means including but not limited to Wi-Fi, cellular networks, Bluetooth, Ethernet cables, serial cables and other data transfer cables. A State of Health (SoH) can be used to proactively identify worn subsystems of components for replacement before they fail or cause a degradation in the user experience. In practice, sensor measurement devices may have significant unit-to-unit variations in accuracy. In some embodiments, the controller and/or the manufacturing process may provide a calibration factor for each sensor measurement device, with the microcontroller applying the appropriate calibration factor(s).

In certain embodiments of the invention, a method of assessing an operational state of health of a personal mobility vehicle includes the steps of:
training a neural network model with training input data reflecting a range of operating states of at least one of a component, a subsystem, or a wheelchair system of the personal mobility vehicle;
gathering operating input data during operation from the one or more subsystems using at least one sensor to receive data measurements associated with an operational state of the one or more subsystems; and
processing the operating input data in a microcontroller to generate additional derived input data using both the data measurements associated with the operational state of one or more subsystems and a time based input, and
providing the derived input data to the neural network model and calculating an output indicative of the operational state of health for the at least one of the component, subsystem, or wheelchair system.

The method may further include the at least one sensor to be configured as one of a voltage sensor, a current sensor, or a temperature sensor. Alternatively, the at least one sensor may be configured as a plurality of sensors provided as one or more voltage sensors, one or more current sensors, and/or one or more temperature sensors. The one or more subsystems may be configured to include a battery, a battery charger, one or more drive motors, one or more actuators, one or more electro-mechanical brakes, or one or more wiring harness and connectors.

In certain embodiments, the training step includes the neural network model being trained to reflect the range of operation states of the component configured as one of a battery, a battery charger, a drive motor, an actuator, an electro-mechanical brake, or a wiring harness and connectors. The output may comprise an expected range of values for SoH or SoC of 0 to 100% for a subsystem including a battery, a battery charger, a drive motor, an actuator, an electro-mechanical brake, or a wiring harness and connectors.

In one aspect of the invention, the training step includes the neural network model configured as a single output neural network model. Alternatively, the neural network model may be configured as a multiple output neural network model.

The invention may be embodied as a personal mobility vehicle that includes a microcontroller; a neural network model, and at least one sensor. The neural network model may reside in or be accessed by the microcontroller and configured to recognize an operating state of at least one of a component, a subsystem, or a wheelchair system of the personal mobility vehicle. The at least one sensor is configured to transmit data measurements associated with an operational state of the one or more subsystems. The data measurements are gathered as input data to be processed by the microcontroller to generate additional derived input data from the data measurements and a time based input. An output is calculated by the neural network model that is indicative of the operational state of health for the at least one of the component, subsystem, or wheelchair system.

The invention may be further embodied as a battery sensor having a battery interface configured as a shunt, such as an electrically conductive bar, rigid element, or an electrical connection such as a wire or cable that permits battery output to be delivered to a connected system. The shunt may include a calibrated portion having known electrical properties such as, for example, resistance. The battery sensor includes a printed circuit board that is electrically connected across the shunt in order to measure battery operational parameters as inputs to the neural network model. The printed circuit board, in certain embodiments, also includes a microcontroller having a neural network model functionalized with training information related to the battery type being monitored. The printed circuit board may further include outputs for at least one of an auxiliary display or an auxiliary communications device to communicate the output of the neural network model indicative of SOC and/or SOH of the battery.

In certain embodiments of the battery sensor, the at least one sensor is configured as one of a voltage sensor, a current sensor, or a temperature sensor. The battery sensor, or battery sensing and monitoring device, may include a local microprocessor with a resident Neural Network model that is configured to determine a battery SOC and/or SOH from raw data measured from the battery and transmit the SOC/SOH data to a display. The display may be configured as a local display, a remote display, or a remote computing device such as a personal computer, smartphone device, or stand-alone, purpose dedicated display each of which may connected by a wired connection. The display may include a reset selector or button that initiates the sensor and display operation from a sleep state to an active state.

In certain configurations, the battery sensor attaches directly to the battery via an integrated shunt. The battery sensor is configured to measure raw battery data and calculate other derived input data with an onboard microcontroller. In certain embodiments, the battery sensor has one or more analog to digital convertors configured to read one or more voltages from the battery, voltage from a current sensor, and/or voltage from a temperature sensor. In an aspect of the invention, the neural network (NN) model(s) is trained prior to deployment with input data derived from laboratory battery life cycle data. The NN model may be a static model that maintains a fixed training background. In other aspects of the invention, the NN model calculates battery SOC and battery SOH.

In certain embodiments, the at least one sensor is configured as a plurality of sensors provided as one or more voltage sensors, one or more current sensors, one or more temperature sensors. The plurality of sensors may measure a voltage level and a current output from at least one location of a battery terminal, and the neural network model calculates a battery state of charge. The sensor measurements are taken over a time period and the neural network model determines a battery state of health. In one aspect of the invention, the neural network model is configured as a single output model.

The at least one sensor may be a plurality of sensors configured to measure a voltage level and a current output from at least one location of a battery terminal and the neural network model calculating a battery state of charge.

Various aspects of this invention will become apparent to those skilled in the art from the following detailed description of the preferred embodiment, when read in light of the accompanying drawings

### BRIEF DESCRIPTION OF THE DRAWINGS

FIG. 1 is a schematic illustration of a power-driven personal mobility vehicle in the form of a wheelchair having a controller configured with a microcontroller containing neural network models in accordance with the invention.

FIG. 2 is a schematic illustration of a plurality of subsystem sensors providing input data to a neural network model which generates an output to one of a display or a memory/communication module.

FIG. 3 is a depiction of various subsystems associated with the wheelchair of FIG. 1.

FIGS. 4A-4C are screenshot images of microcontroller output screens showing neural network model outputs of battery state of charge and state of health.

FIG. 5 is a table of electrical subsystems, associated sensor raw input data and calculated input data, and outputs.

FIG. 6 is a photograph of a battery sensor in accordance with the invention.

FIG. 7 is a photograph of an auxiliary display and related circuit in accordance with the invention.

FIG. 8 is a photograph of an auxiliary communication circuit and device in accordance with the invention.

FIG. 9 is a schematic illustration of a battery sensor in accordance with the invention.

FIG. 10 is a schematic illustration of an auxiliary display configured for use with the battery sensor of FIG. 9.

FIG. 11 is an auxiliary communications device for use with the battery sensor of FIG. 9.

FIG. 12 is an operational flow diagram of a battery state monitor in accordance with the invention.

FIG. 13 is a schematic illustration depicting operation of a battery state monitor.

### DETAILED DESCRIPTION

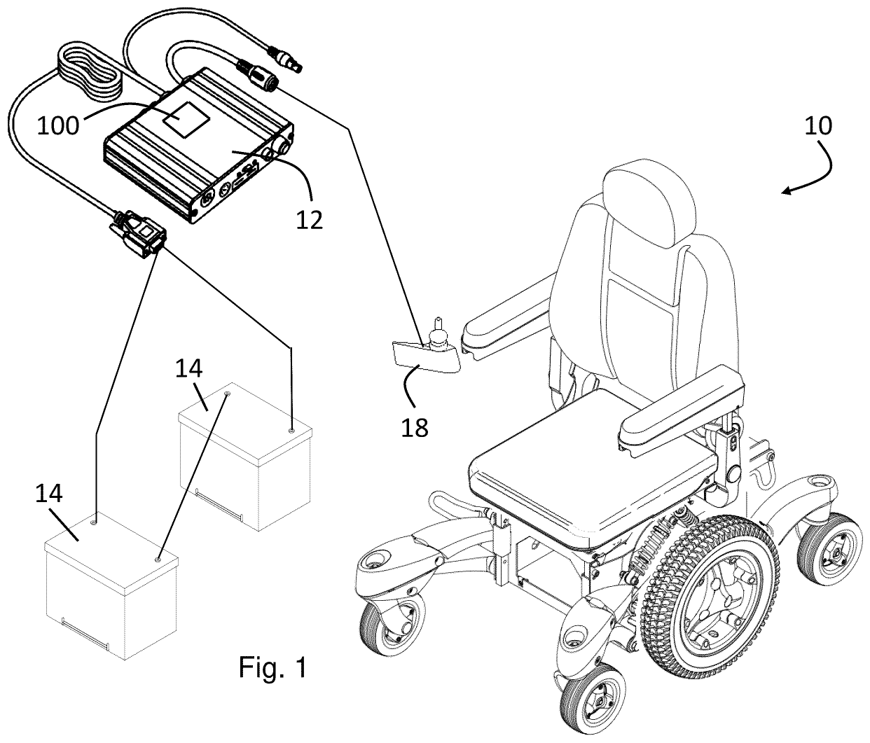

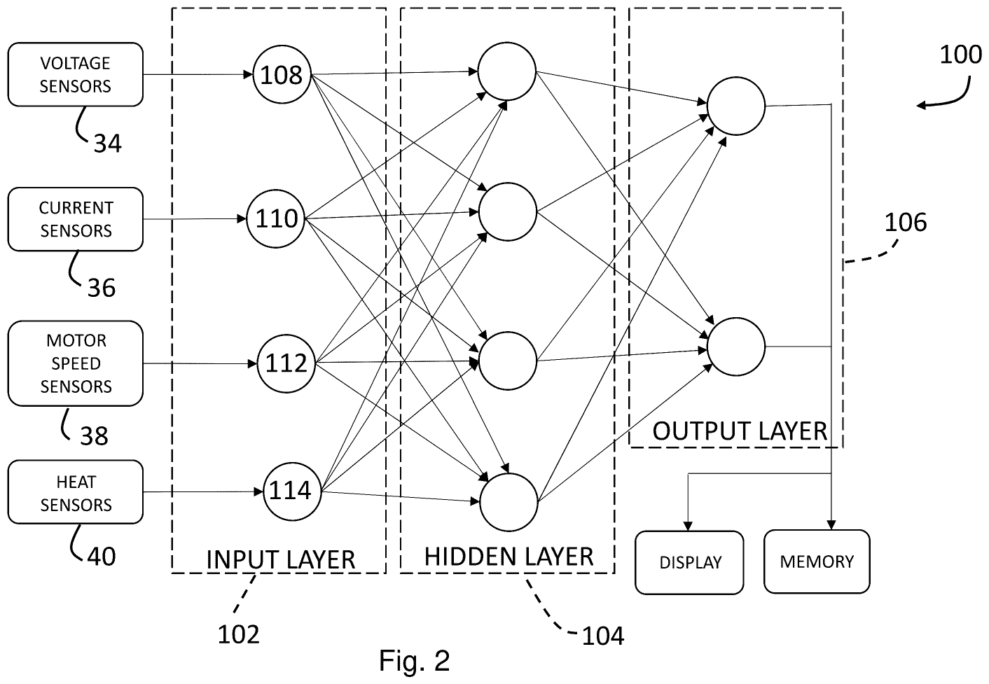

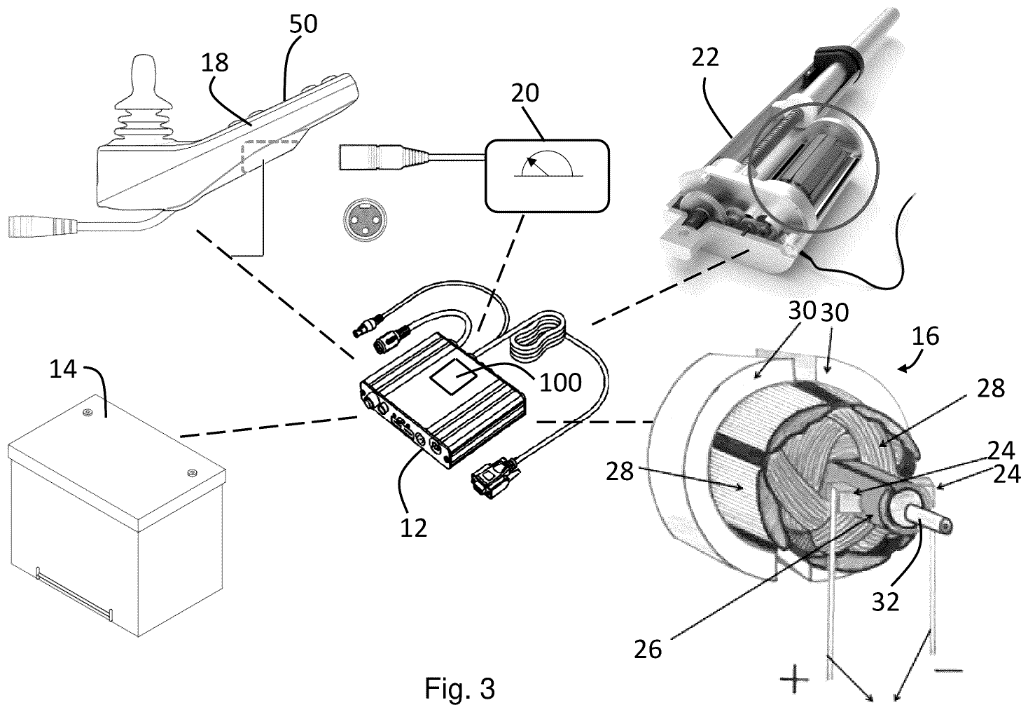

Referring now to the drawings, there is illustrated in FIG. 1 an example of a personal mobility vehicle shown generally at 10. The personal mobility vehicle 10 is shown as a power driven wheelchair. The wheelchair 10 includes a controller or microcontroller 12 that includes or is in communication with a neural network model (NNM) 100, as shown in FIG. 2. In some embodiments, the NNM 100 is configured to monitor one or more electrical of a power-driven personal mobility vehicle in accordance with the invention. In some embodiments, the wheelchair 10 includes a battery 14 as an energy source to power drive motors 16 that propel the wheelchair in response to user inputs from a control device, such as a joystick 18, and as shown in FIG. 3. These electrical and electro-mechanical subsystems are in communication with the controller 12 to operate the wheelchair in response to user command inputs. In addition, accessory systems such as charging units 20 that maintain battery power and actuators 22 are also connected to the controller 12 to operate in response to command inputs. Many of these subsystems include mechanical elements, such as bearings, windings, brushes, commutators and other contacts that impact the electrical response of the devices. In addition, sensors that may measure voltage, current, temperature, speed (rotational or linear), impedance, capacitance, resistance, vibration, and/or time are in communication with the controller 12. The NNM 100 receives one or more of these sensor outputs and evaluates the data through an algorithm constructed from training data in order to determine its state of health.

In one embodiment, the NNM 100 may measure parameters associated with the operation of an electric motor, such as one or more of the drive motors 16. One type of drive motor 16, as shown in FIG. 3, is a DC motor that includes brushes 24, commutator 26, windings 28, permanent magnets 30, and bearings 32. Other types of electric drive motors, such as variable reluctance motors, DC motors, AC motors, brushless DC or AC motors, may be used and remain within the scope of the invention. As the motor is commanded to propel the wheelchair 10, power is sent to the motor windings in a conventional manner to drive the armature and create motion. The power can be measured as a combination of voltage and current, which are examples of inputs that may be sent to the NNM 100. Based on the load demand of the wheelchair and the user input from the joystick, heat is created. The heat may be a function of several factors such as, for example, the rate of acceleration demanded by the user, mechanical resistance of the bearings 32, inertia of the wheelchair 10, and contact status of the brushes 24 and commutator 26. The NNM 100 receives some or all of these inputs, as depicted in the schematic illustration of FIG. 2, to determine if the drive motor subsystem is operating within an acceptable performance envelope or if a particular element is beginning to wear to excess.

As the NNM 100 receives data values for the measured or derived model input data, optionally via an input layer 102, the model determines, optionally via a hidden layer 104, outputs, optionally via an output layer 106 indicative of subsystem operation based on the trained algorithm of the model. For example, the drive motor 16, configured as a brushed DC motor, may include one or more voltage sensors 34, one or more current sensors 36, a motor speed sensor 38, and/or one or more temperature sensors 40. These sensors are used to generate raw data of motor performance, including motor winding or brush contact input voltage and current values, and operating temperature at a series of speeds. As the motor wears, these values will change over time. These performance data values also change with the load demand and speed of the motor. The NNM 100 receives the input data and is configured to determine the health state from 0 to 100%.

In some embodiments, measurement data from the voltage sensors 34, current sensors 36, motor speed sensor 38, and temperature sensors 40 are used by the NNM 100 to calculate a State of Health (SoH) of the various subsystems. Resistance may be calculated by the microcontroller 12 using data from voltage sensors 34 and current sensors 36. For example, if the motor brushes are wearing or have become dirty or damaged, the resistance of the circuit of the brush and commutator will likely increase. This resistance increase will generate a corresponding increase in overall motor temperature as measured by the temperature sensors 40 for a predetermined operational demand, and may further cause the windings to demand increased current to achieve the desired motor operation. This increased current can be detected by the current sensors 36. Examples of other powered wheelchair sub-systems that can be monitored by the NNM 100 for SoH include actuator motors, electro-mechanical brakes, batteries, battery chargers, and wiring harnesses and connectors.

When monitoring a power system, such as the battery 14, the NNM 100 can determine a State of Charge (SoC) and/or the SoH of the battery. The SoC can be defined as the amount of charge of the battery compared to a full charge state. In descriptive terms, the state of health is 100% for a new battery and 0% for a failed battery. In one example of battery performance metrics, the SoH can be defined as the full discharge capacity of a battery, in Amp-hours (Ah), divided by the initial (new) capacity of the battery in Ah. In one example, the microcontroller measures current, voltage, and temperature of the battery. Some additional parameters associated with battery SoH may be derived by calculations utilizing time-based metrics of operation.

The voltage of the battery 14 is measured by one or more voltage sensors 34 that supply input data to the NNM 100 through the microcontroller 12. Similarly, the current of the battery is measured by one or more current sensors 36 that supply input data to the NNM 100 through the microcontroller 12. Additionally, the temperature of the battery is measured using one or more temperature sensors 40 that supply input data to the NNM 100 through the microcontroller 12.

In one embodiment, the power-driven personal mobility vehicle is a powered wheelchair, and the battery 14 is a lead acid battery. Any type of lead acid battery is possible, including; wet or flooded, absorbent glass mat (AGM), or gel battery designs. Alternatively, the battery may be any electro-chemical storage device configured to store and release electrical power such as, for example, a lithium-ion battery, a nickel-metal-hydride (NiMH) battery or a nickel cadmium battery. In one embodiment, the battery 14 is a battery bank that includes a plurality of batteries 14, connected in series, in parallel, or in a combination of series and parallel, that may be arranged as battery modules. In a preferred battery embodiment, two 12V modules are connected in series to yield a 24V battery. The powered wheelchair may include a controller or microcontroller 12 configured to measure key data associated with battery charge level and battery health, to implement the NNM 100, and to output a status indicator of the battery 14 on a display 50. Alternatively or additionally, the battery status may be stored in a memory portion of the controller 12 or in a remote storage medium such as the cloud. The memory can be implemented using any computer-readable storage medium, such as random-access memory (RAM), a Universal Serial Bus (USB) thumb drive, a data storage drive, or any other type of computer storage media.

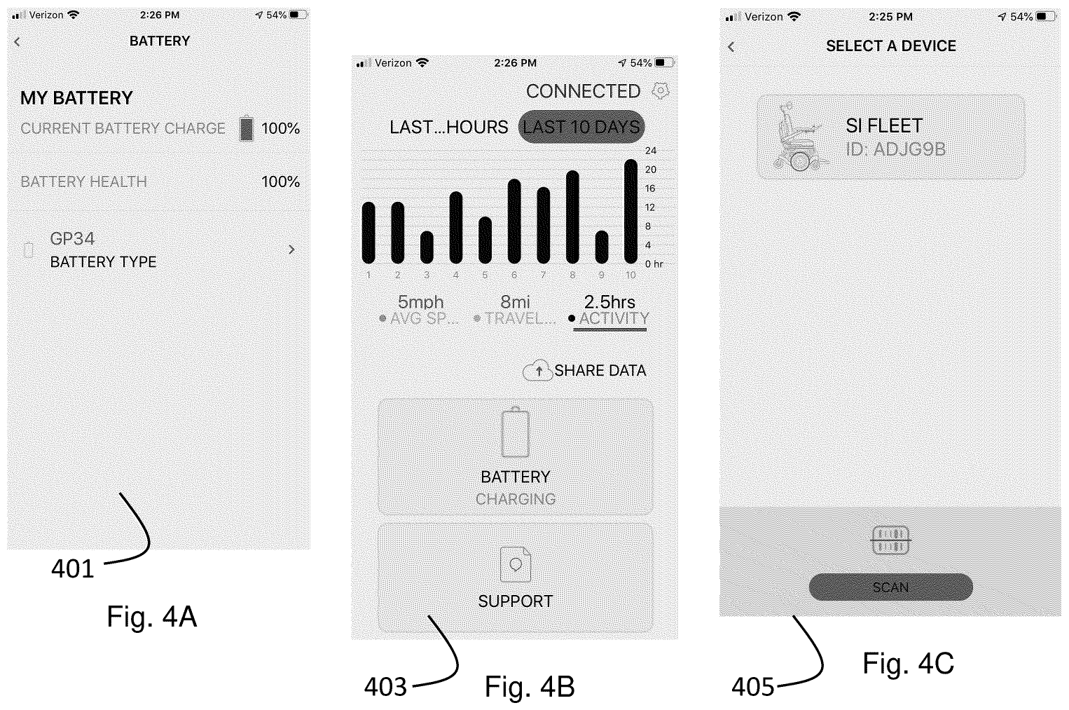

The battery 14 may be connected to one or more sensors such as voltage sensors 34, current sensors 36, and temperature sensors 40 to measure battery parameters. Sensors related to battery charge information, such as charger output, and charge time from an initial voltage measurement to a predetermined voltage level or range, for example 12.8-13.4 volts may also be inputs to the NNM 100. In addition, other sensors or information that are indicative of wheelchair operational duty cycles between charging events may be used by the NNM 100 to assess SoC and SoH of the battery. An example of an output of information relating to the battery 14, for example a SoC of 100% and a SoH of 100%, is shown in FIG. 4A by screenshot 401 of display 50. Further information on the battery 14 and the personal mobility vehicle 10, like an average speed of 5 mph (8,046 km/h), a travel distance of 8 mi (12.87 km) and an activity of 2.5 hours can be displayed on display 50 as shown in FIG. 4B by screenshot 403. These data can be displayed for different time spans, for example for the last 10 days or a specific number of last hours.

The NNM 100 comprises a plurality of neurons organized into layers such as, for example, an input layer 102, a hidden layer 104, and an output layer 106 as shown in FIG. 2. The input layer 102 receives input data from the various sensors such as the one or more voltage sensors 34, one or more current sensors 36, the motor speed sensors 38, and one or more of the heat and/or temperature sensors 40, or any of various combinations thereof. The input layer 102 may include a plurality of neurons such as a first neuron 108, a second neuron 110, and a third neuron 112. The hidden layer 104 and the output layer 106 may include any number of neurons within each layer necessary for organizing and processing input data and calculating system operational outputs. In a typical NNM 100, the sensor data may be input data used in individual input neurons, such as the voltage sensor data 34 connected to the first input data neuron 108, the current sensor data 36 connected to the second input neuron 110 and the motor speed sensor data connected to the third input neuron 112. For both State of Health (SOH) and battery State of Charge (SOC) models the single output node model is preferred. In a single output node configuration, the model is mapping the sensor data or derived input data to the output resulting in the highest accuracy and lowest errors (relative to multiple output node models). The use of a single output node model is preferred when there is only one output metric possible or desired.

For purposes of illustration as shown in FIG. 2, in one embodiment data from the voltage sensor 34 may be used by the first neuron 108. Data from the current sensor 36 may be used by the second, or third neurons 110 and 112. Data from the motor speed sensor 38 may be used by the other of the second or third neuron 110 or 112. Data from the heat and/or temperature sensor 40 may be used by the fourth neuron 114. The connections of the sensor data to neurons in the input layer 102 are shown for purposes of illustration, as other topologies also fall within the scope of the invention. The hidden layer 104 generally represents weighted combinations of the input neurons and the output layer 106 is a final output which may be a SoH, SoC, or other output indicative of subsystem operation. The outputs may be sent to a display, such as a joystick screen or smartphone to alert the user to current system status and potential operational anomalies.

In operation, the NNM 100 processes the input data to monitor and diagnose a subsystem of the personal mobility vehicle. Typically during normal operation when one or more of the subsystems of the personal mobility vehicle are functioning properly, the NNM 100 gathers parameter data from the one or more subsystems using the plurality of sensor data operatively coupled to the input layer 102. Next, the NNM 100 processes the received parameter data to determine an expected result of the data for the one or more subsystems. The microcontroller stores the results in the controller memory or remote data storage location. For example, the expected result may relate to a specific subsystem state of a singular component.

FIG. 4C illustrates a scenario where the wheelchair 10 is part of a fleet of wheelchairs that may be monitored and diagnosed remotely.

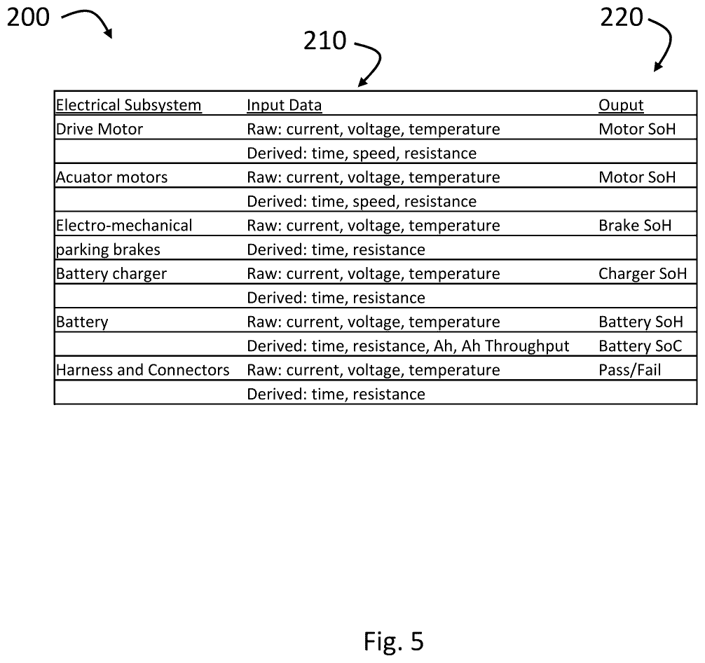

FIG. 5 is a table of electrical subsystems 200, associated input data parameters 210, and predictive output assessments 220. More specifically, the table provides an association of various electrical subsystems 200 of wheelchair 10 with input data 210 that are measured or derived to determine the State of Health (SoH) using the applicable NNM. The interactions of these elements with other subsystems can inform and pinpoint if anomalous data is indicative of a true internal component issue, a larger system interaction problem, or just normal operation where the subsystem health is not yet impacting the chair performance. By having the added capability to look at other subsystem data points such as joystick control position and drain rate of the batteries 14, and accurate life predictions can be determined. For example, if the physical connection between the battery charger 20 and the battery 14 is faulty, a regulator in the battery charger 20 may indicate that the battery is fully charged, but the SoC of the battery may indicate otherwise. The lack of full battery charge may cause higher temperatures in the brushed DC motor 16 because of a lower voltage and an associated higher current draw to maintain motor torque/speed.

Returning now to FIG. 4C, showing a display output screenshot 405 of display in addition to individual unit monitoring and health assessments, fleet management based on multiple unit data sets can improve design by pinpointing component issues and help sort out whether failures are based on design or manufacturing and shipment lot considerations. The gathering and manipulation of data can be done locally by the wheelchair controller or transmitted to a central processing facility via cloud-based data exchange.

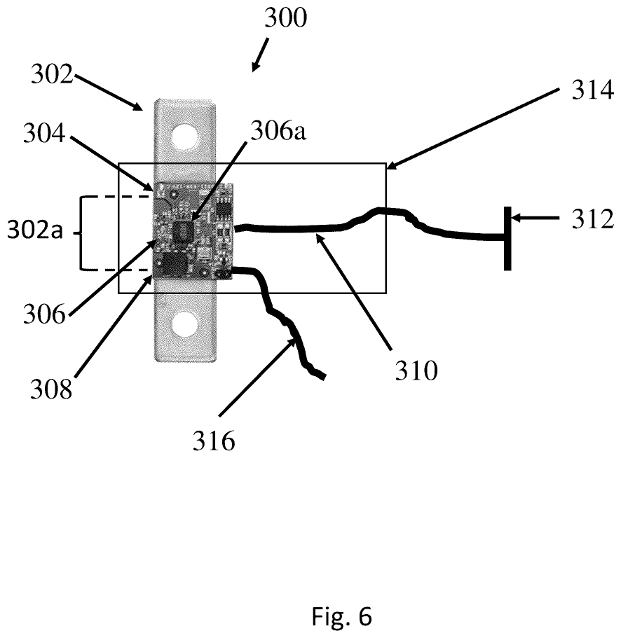

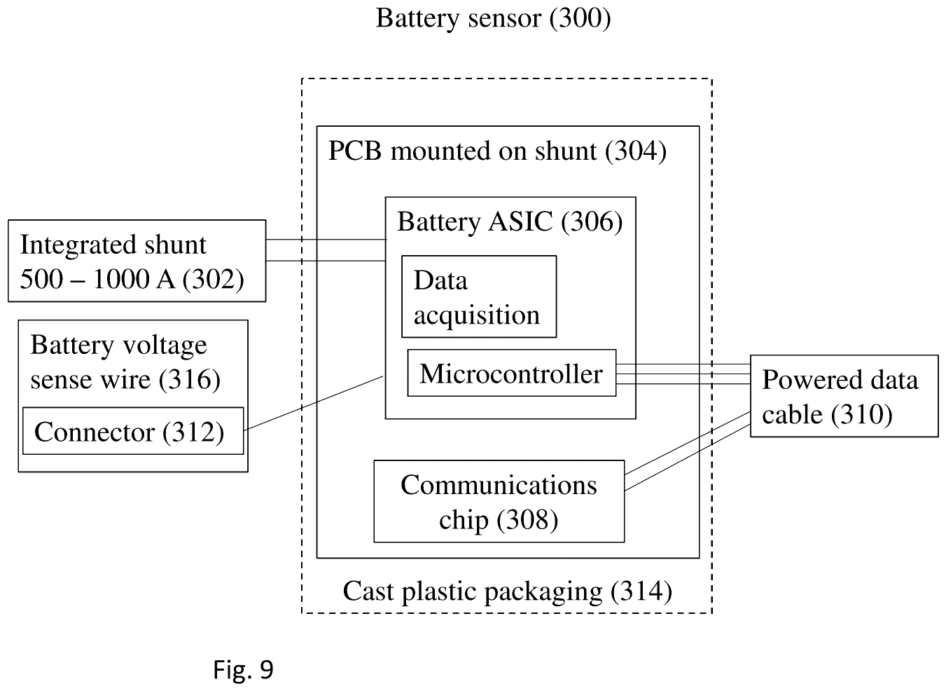

Referring now to FIGS. 6-11, embodiments of a battery sensor 300 is shown photographically and schematically. The battery sensor 300 includes a shunt 302 that establishes electrical communication between a terminal of the battery and an external load or device. A printed circuit board (PCB) 304 is mounted onto the shunt 302. In certain embodiments, the battery sensor 300 may be mounted in close proximity or directly onto the battery terminal. In one embodiment, the PCB 304 includes Application Specific Integrated Circuits (ASIC) 306 that may be tailored to battery data acquisition or other data acquisition schemes. The ASIC 306 includes a microcontroller 306a and can be combined with features such as communication protocols, current integration function, and on-chip or on-printed circuit board temperature measurements to augment the data acquisition and microcontroller computation functions through the NN model. The battery sensor 300 may also connect to or include other chips or circuits on the PCB 304 such as an auxiliary display circuit 400 and/or an auxiliary communication circuit 500. While ASIC microcontrollers 306a may have limited programing flash memory and data memory, a simple method of utilizing one focused equation of the NN models alleviates computational complexity and provides the ability to run sophisticated models on an ASIC microcontroller.

The battery ASIC 306 is configured to provide several functions including but not limited to: data acquisition, computer control, NN model processing and data communications, along with other cursory or operational functions. In one embodiment, data acquisition by the ASIC microcontroller 306a may be configured for at least 16 bit processing of voltage and current data to provide for sufficiently discretionary measurement sensitivity. Additional input data are derived from the raw input data and the time base provided by the ASIC microcontroller 306a. For example, the ASIC may integrate current (raw data) over time (time base) to yield Amp-hours (Ah). Properties such as internal battery resistance can be obtained from voltage and current raw data. Other derived input data can be generated using the raw data, derived data and time base data collected by or determined by the ASIC. In one embodiment, the calculations performed by the microcontroller and software (a.k.a. firmware) may be written in a C or C++ programming language to take advantage of processing efficiencies and maximize data storage and microprocessor computational space.

In certain embodiments, the NN models may be distinct for SOC and SOH determinations along with NN models for charge and discharge events. One attribute of NN models is their efficiency and accuracy when operating on very large data sets, such as machine learning and machine vision. The NN model is represented by one multiple input equation, which can be calculated fast with minimal programming space and work well with large numbers of repeatable calculations due to the calculation speed capability. By way of example, in machine vision applications where the data consists of millions of pixels, each pixel is calculated independently with a NN model. For a battery sensor according to the invention, the NN model 100 resident in the battery ASIC 306 has a small code requirement, allowing its use with limited memory ASICs.

As stated previously in conjunction with NN models directed at various personal mobility vehicle systems, the battery models for SOC and SOH are created beforehand by training the models with battery laboratory life cycle data. The input data for SOC are selected to reflect the changes in SOC over a discharge or a charge event, which will also change over battery life. The input data for SOH reflects changes in SOH over the life of the battery. The NN models of the battery ASIC 306 create a battery life data pattern in multi-variable space. Once established for a given battery architecture or application, the models are static and need no further training during use. The NN models use the multiple input data from the real time, raw and derived data to calculate the state (either SOC or SOH depending on model) closest matching the input data. While the NN model are accurate approximations of the target battery parameter being monitored, they can take into account the entire battery life, as opposed to just one point in time, such as the new battery operating characteristic. Amp-hour counting methods do not have this capability.

The PCB with the battery sensor ASIC is then mounted directly onto the integrated shunt 302. In one embodiment, the integrated shunt 302 is made of strong, electrically conductive metal with a resistance area 302a of precise resistance (typically 0.1 milliohm but other values may be used and are within the scope of the invention) and capable of conducting up to 1000 amps for certain applications. The ASIC is connected by two leads on each side of the resistance area 302a to allow the voltage drop across the resistance area to be measured, which is directly proportional to the current. In one embodiment, the resistance area 302a also defines a controlled distance between the connected leads of the ASIC 306 to establish a resistance datum as the resistance reference point for other electrical calculations. Other means for current sensing are possible and in accordance with the scope of the invention.

The battery sensor 300 has at least one microcontroller, such as ASIC microcontroller 306a, that has the NN models 100 in its memory and can execute the calculation of the NN models. The NN models can use multiple input data to calculate outputs of SOC or SOH. The battery sensor 300 further includes means to collect raw battery data in the form of battery current, battery voltage, and battery temperature. The battery sensor 300 includes analog to digital converters (A/D converter) to collect data such as direct measurements of battery voltage, and direct measurements of current and temperature. Other input data can be calculated using these raw data in combination with each other or with time (from the microcontroller time base). In one illustrative example, a calculation by the microcontroller can be to divide the change in voltage for two data points by the corresponding change in current to yield the battery internal resistance.

The ASIC or microcontroller has the ability to transition into a sleep mode or low power consumption mode when the battery is at rest. This may reduce the battery sensor operation current by a factor of 100 or more, thus minimizing parasitic current draw that can discharge the battery over time. The battery sensor 300, including the ASIC or microcontroller, can be awoken based on a charge or discharge event where current on the shunt is greater than a threshold amount. In one example, the threshold current value may be in a range of about 75 mA to about 150 mA, or be around 100 mA. The battery sensor 300 can also wake up due to a voltage signal on a powered cable, such as a powered data cable 310. The voltage signal may originate from, for example, an internet connection, a display prompt, or other user-interface operation. If a simple display is connected, the wakeup can be done with a manual push button on the display.

The battery sensor 300 may include a communication chip 308 for translating NN model output data into an appropriate communication protocol and transmitting the data to a system output. The communication protocols include but are not limited to: serial bus (RS232 and others), serial/parallel bus (SPI), CAN bus (automotive protocol) and local interconnect network (LIN, also an automotive protocol) among many others. Alternatively, communication protocols may be resident in the ASIC 306 and not require a separate communications chip if there is processing capacity available. The communication data is then transmitted from the PCB 304 or communications chip 308 to a powered data cable 310 and its multi-pin connecter 312. Depending on the communication protocol, the cable 310 may have any number of communication wires but typically will utilize from one to four communication wires in the powered data cable 310. The powered data cable may also have simple input/output (I/O) wires that could be used to turn auxiliary equipment on and off. In one embodiment, the auxiliary equipment may be a battery charger. In one embodiment, the I/O consists of a two wires where one is ground and the other is either an off (0 V) or on (5V) state and configured to control external devices such as a charger using a relay on the AC power for the device. The powered data cable 310 also has a power supply connection, that may utilize one or two wires to provide electrical power from the ASIC power supply to the auxiliary connected devices as will be explained below. This will typically be a 5V source, but other voltages are possible. In addition, the cable 310 also will carry a wakeup signal, which may be through a separate wired connection, such as two wires for communicating a change in battery activity status. This is typically a voltage signal, although other signals are possible, from the auxiliary device such that when the signal is received by the ASIC 306 it will wake up if in sleep mode. The cable 310 is terminated with a multi-pin electrical connector 312 for purposes of connecting the cable 310 to auxiliary devices. In one embodiment, the pins of the connector 312 may be female in order to protect against contact with a live voltage signal. Both the cable 310 and connector 312 are durably constructed and may be selected for water and dust proof capabilities.

To facilitate the connection of the battery sensor 300 with either a display or internet connection hardware, in certain embodiments, the sensor can include a powered data cable 310. The data cable 310 is connected to the battery sensor 300 and terminated with a multi-pin connector 312. The mating portion of the connector 312 also has a powered data cable that attaches to an auxiliary display 400 or an auxiliary communication device 500 which may be configured as an internet connection device. In one embodiment, the powered data cable may be configured to use a low voltage power of about 5V DC. The PCB 302 has a battery voltage sense wire 316 that is normally connected to the most positive terminal of the battery or pack. Both the battery voltage sense wire 316 and the shunt 302 are desirably of a low resistance configuration, however, any number of auxiliary connectors may be used to facilitate connection to the battery terminals since battery terminals may exist in many forms. The PCB may have more than one battery voltage wire 316, where a first battery voltage wire connects to the most positive terminal of the battery or pack and a second battery voltage wire connects to a lower voltage, positive battery terminal. The second battery voltage connection may be used as a power supply for the ASIC 306 and PCB 302.

The battery sensor 300, along with the auxiliary display 400, and/or the auxiliary communication device 500, may be packaged in a chemically and moisture resistant package, such as a cast plastic housing 314, 410, and/or 510 formed from a cast acrylic, epoxy, polycarbonate, or polyester block. Since the battery sensor, and other auxiliary systems, may be subjected to corrosive agents, dust, water or other environmental contaminants, a packaging process that eliminates seams or other potential intrusion points is advantageous. It may also be desirable to encase the electronics in a potting material to add shock resistance. It may also be desirable to encase the electronics in an opaque potting material to protect against reverse engineering. In certain embodiments, the cast plastic packaging 314 fully encapsulates the PCB 304, ASIC 306 and the communications chip 308 and may partially encapsulate the shunt 302, the powered data cable 310, and the battery voltage sense wire 316. Alternatively, a formed housing made from the cast polymer material may be used.

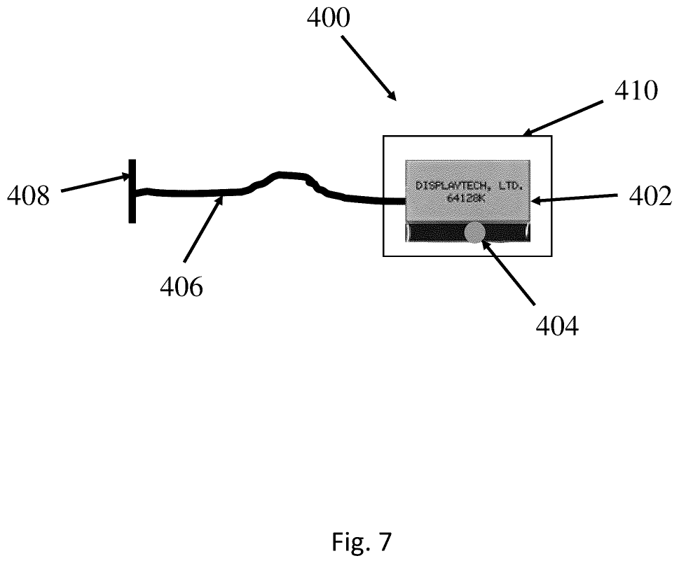

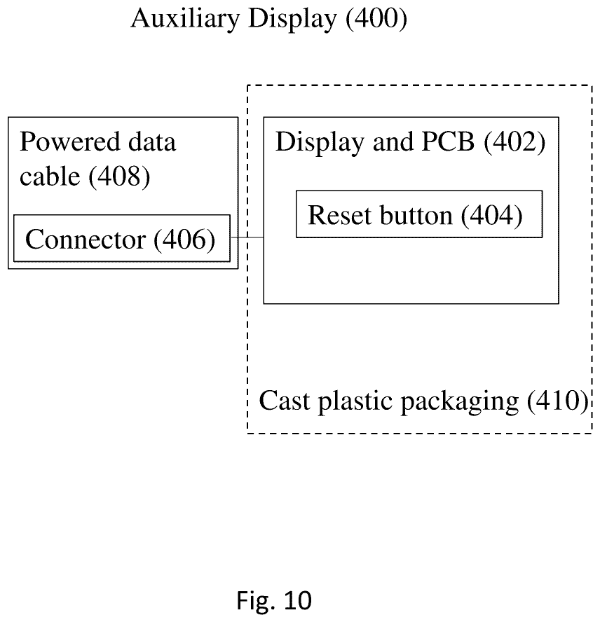

Referring now to FIGS. 7 and 10, the auxiliary display 400 is used to display the NN model output data of the SOC and SOH. The display output may be any easily recognizable format, such as an integer from 0 to 100, a bar graph optionally color-coded for example from green (full) to yellow (partial discharge) to red (low power level), or an analog needle indicator. The display 400 may display other information related to the battery sensor, such as real-time power draw, battery temperature, current, or voltage output. The display 400 may display other information related to the battery sensor, such as the need to charge the battery. The display 400 has an associated PCB 402 having chips or electronics corresponding to the communications protocol in use by the ASIC 306 or other communications circuit. In certain embodiments, the display 400 may be powered by the PCB 304 or the ASIC 306 via a powered data cable 406 and connector 408 which mates to the connector 312 from the PCB 304. The powered data cable 406 can be of variable length to allow remote mounting of the display 400 from the battery and battery sensor 300. In certain embodiments, the display 400 may include lighting and enter a sleep mode having a darkened display after a period of inactivity from the system. The display 400 may include a reset button 404 which may be integrated with the display 400. The reset button 404 may be configured to change the display to a different mode, wake up the display 400 to display the most recent SOC and SOH data, and may function to wake up the ASIC 306. The auxiliary display 400 may also be encapsulated in a cast plastic packaging 410, similar to the cast plastic packaging 314 of the battery sensor 300. In certain embodiments, the output screen of the display 400 and/or the reset button 404 may extend beyond the encapsulation.

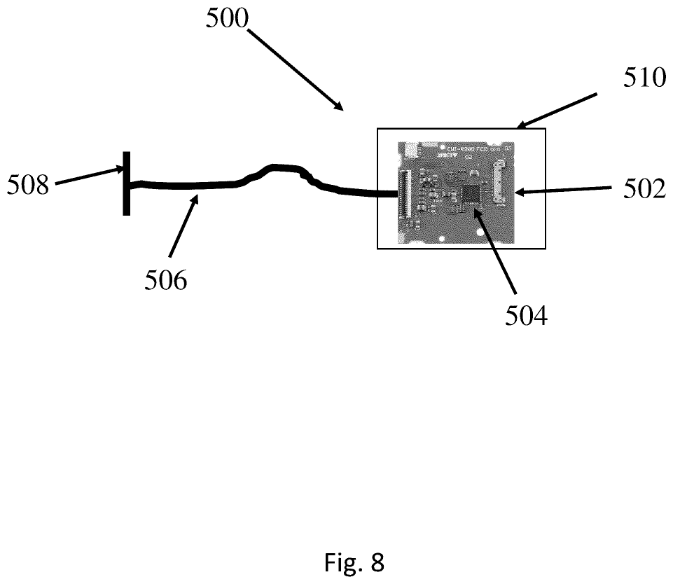

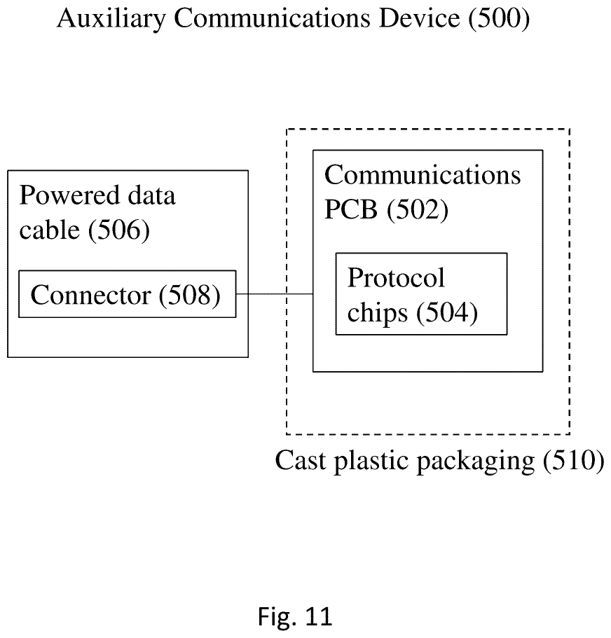

Referring now to FIGS. 8 and 11, the auxiliary communication device 500 comprises a communications PCB 502, one or more protocol chips 504, a powered data cable 506 terminating in a connector 508, and an encapsulant or cast plastic package 510. These components work together to provide the following functions:
Data transmission of SOC, SOH, and other information to remote displays, processors, databases, or the internet
Monitoring of predetermined threshold and actuation of PCB power down (sleep mode)
Communication link for initiating wake up signal to the PCB 502 from outside sources
Powered cable providing data transmission, electrical power to the PCB 502 and wakeup signal back to the ASIC 306
Connecting the communications device 500 to the battery sensor 300 via the powered cable 506 and connector 508
IO signals to turn auxiliary equipment on and off, one embodiment being a battery charger.

The auxiliary communications device 500 is used to transmit the NN output data of the SOC and SOH to other devices, including but not limited to the auxiliary display 400, other computers, and to the internet. The auxiliary communications device 500 may transmit other information related to the battery sensor 300 as well. The auxiliary communications device 500 has an associated communications PCB 502 which includes protocol chips 504 or electronics corresponding to both the communications protocol in use by the ASIC 306 and the communications protocol used to transmit to other computers or the internet. The protocol for external transmission may include but is not limited to: Wi-Fi, Bluetooth, GSM and other cellular phone based methods (e.g., 3G, 4G), Ethernet cables, dial-up with a computer modem via telephone circuits, broadband over coaxial cable, fiber optics or copper wires and satellite communications.

The PCB 502 is powered by the battery sensor PCB 304 or ASIC 306 via the powered data cable 506 and connector 508 which mates to the connector 312 from the PCB 302. The powered data cable 506 can be of variable length to allow remote mounting of the display device 500 from the battery and battery sensor 300. The protocol chips 504 may include a low power mode, which can be entered after a predetermined timeframe of inactivity (sleep mode). A wake up signal may be generated by, the auxiliary display 400 via the reset button or the other devices such as other connected computers. In certain embodiments, upon entering a reactivated state, the protocol chips 504 may transmit the most recent SOC and SOH data or other data. Reactivation of the communications device 500 may also activate the battery sensor 300 or ASIC 306.

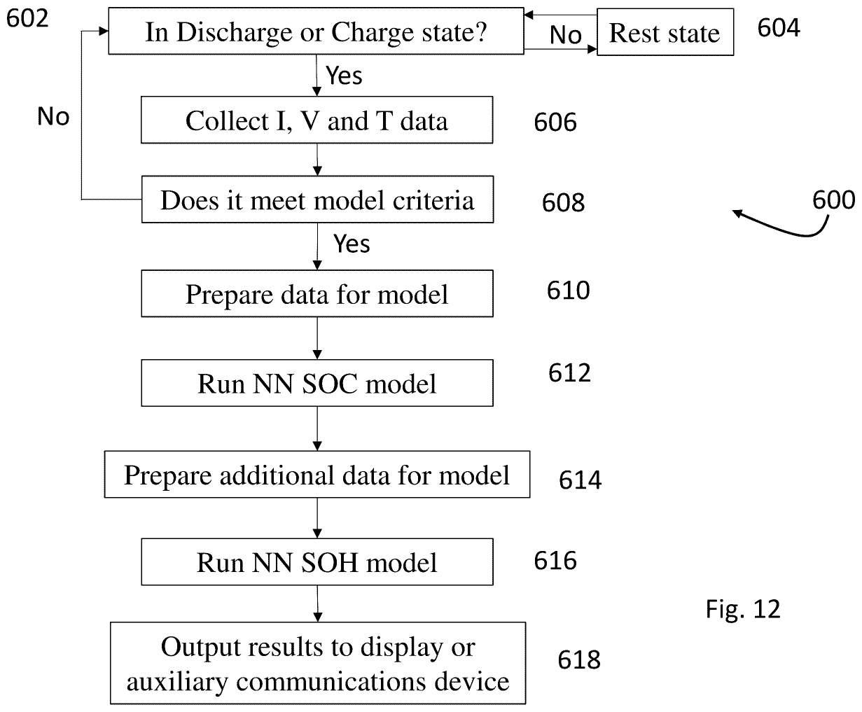

Referring now to FIG. 12, a flow diagram of the operational steps of the software are illustrated. At step 602, the battery sensor 300 or ASIC 306 determines if the there is a charge or discharge event occurring. If not, the system moves into a rest or sleep mode 604. Once a battery event has occurred, data is collected at step 606. The data collected may be one or more of current, voltage and temperature raw battery data. At step 608, the data is compared to a preset model criteria to determine if the battery event necessitates an update of the battery SOC and/or SOH or other model measurement parameter. If the preset model criteria is met, the data is prepared for input into the NN model. This step helps conserve computing resources for the ASIC 306. The NN Model run is initiated in step 612 for determining a battery SOC. At step 614, additional data is prepared for a NN model run to determine SOH at step 616. The output of the NN model is sent to the auxiliary display 400 and/or the auxiliary communication device 500 at step 618.

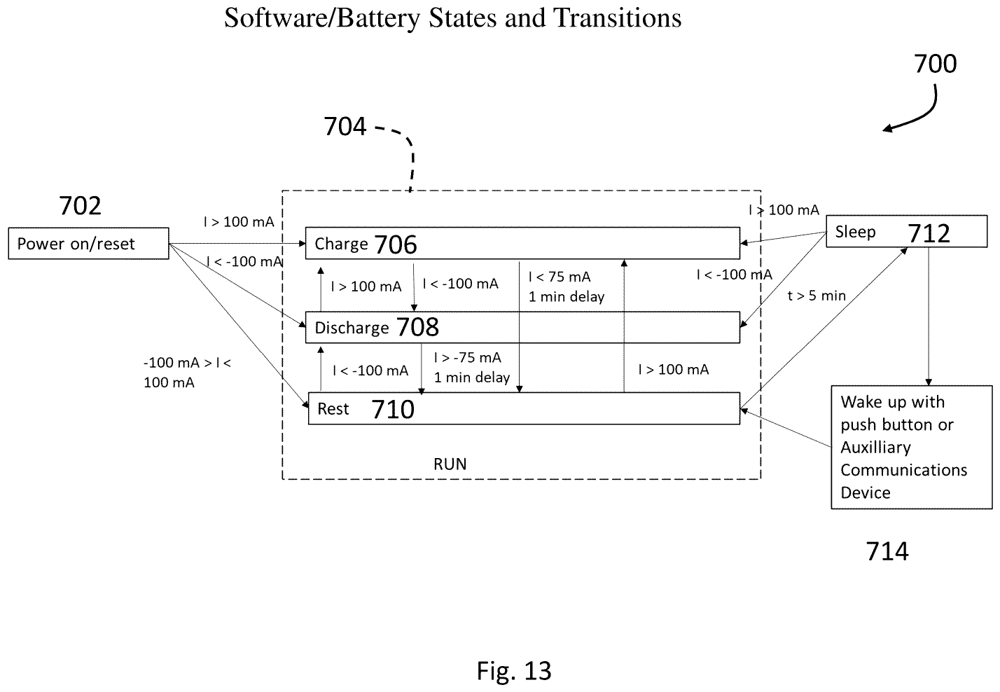

Upon a power on or reset event, the battery sensor 300, through the ASIC 306 will go through an initialization sequence not shown in the figure. After initialization, the software will be in one of the three run states. The loop is described in FIG. 13 and may be configured to repeat at a frequency from 0.1 s to 10 s with 1s being a preferred embodiment.

Referring now to FIGS. 13, operational software in the battery sensor 300, generally, and the ASIC 306, specifically, functions primarily as a loop. The software and battery have defined states, namely:
Off 702 (electrically disconnected from battery);
three Run states 704: Charge 706, Discharge 708, and Rest 710;
a low current Sleep state 712 for when the battery is not active. The states are determined by the current flow and time as shown in FIG. 13.

When first connected or after a reset, the current will determine the Run state 704. For currents less than −100 mA, the system enters the Discharge state 708. For currents greater than 100 mA, the system enters the Charge state 706. For currents in between these thresholds, the system enters the Rest state 701. These are typical thresholds for current and time for a given embodiment and can be changed.

Within the Run states 704, the transition to other Run states is determined by current and time. Transition to the Sleep state only occurs from the Rest state 710. When in the Rest state 710, the state will change to the Charge state 706 when the current goes above 100 mA or will change to a Discharge state 708 when the current goes below −100 mA. If the Rest state 710 has been active for greater than 5 minutes, it will go to the Sleep state 712. In certain embodiments, when operating in the Discharge state 708, the state will transition to the Charge state 706 when the current goes above 100 mA. If the current becomes greater than −75 mA but less than 100 mA for a predetermined time period, such as one minute, it will transition to the Rest state 710. When in the Charge state 706, the state will transition to the Discharge state 708 when the current goes below −100 mA. If the current goes less than 75 mA but more than −100 mA for the predetermined time period, it will transition to the Rest state 710.

When in the Sleep state 712, most functions of the Battery ASIC 306 will stop to reduce current draw to minimum levels. The display 400 will also be off. However, the Battery ASIC 306 will still monitor any activity on the shunt 302, the display reset button 404 or the powered data cables or communication lines. When current greater than 100 mA is sensed, the state will transition to the Charge state. When current less than −100 mA is sensed, the state will transition immediately to the Discharge state. When either the reset button wake up or communications line wake up are activated, the state will transition to the Rest state.

The principle and mode of operation of this invention have been explained and illustrated in its preferred embodiment. However, it must be understood that this invention may be practiced otherwise than as specifically explained and illustrated without departing from its spirit or scope.

What is claimed is:

1. An energy storage device sensor comprising:
a shunt defining a resistance area;
a printed circuit board in electrical communication with the resistance area through two spaced-apart electrical contacts that establish a resistance datum, the printed circuit board having a powered data connection and further including a microcontroller having a memory and a processor, the microcontroller including a data acquisition input to receive raw data from the shunt resistance area; and
a static neural network model resident in the memory and configured to calculate and output at least one of a energy storage device state of charge or a energy storage state of health.

2. The energy storage device sensor of claim 1 connected to an energy storage device configured as one of a chemical battery, a fuel cell, or a capacitor, and the shunt includes a first end attached to a first terminal connection of the energy storage device and the a second end connected to an external load.

3. The energy storage device sensor of claim 2 wherein the raw data comprises at least one of battery voltage, battery current, battery temperature, or time and wherein the output comprises a value for the state of health or the state of charge of in a range of 0 percent to 100 percent of a new, unworked energy storage device.

4. The energy storage device senor of claim 1 connected to an energy storage device configured as a chemical battery, and wherein the raw data is at least one of a voltage measurement, a current measurement, or a temperature measurement;
the microcontroller configured as a battery application-specific, integrated circuit controller, the static neural network model configured with training data directed to a battery chemistry configured as one of a lead-acid chemistry, a lithium-ion chemistry, a nickel-metal-hydride chemistry, or a nickel hydrogen chemistry and including test-generated life cycle data; and
the printed circuit board in electrical communication with a powered data cable that comprises at least one of a low voltage power supply, one or more communication lines for digital communications, or input/output wires configured to provide one of a sensor activation state from a rest state or an auxiliary device power switch.

5. The energy storage device sensor of claim 4 wherein the microcontroller is configured to move from the rest state to the activation state when the input/output wires transmit one of a charge event or a discharge event wherein a detected current on the shunt is greater than a threshold current value.

6. The energy storage device sensor of claim 5 wherein when the input/output wires transmit the charge event, the threshold current value is above about 100 milliamperes, and wherein when the input/output wires transmit the discharge event, the threshold current value is below about −100 milliamperes.

7. The energy storage device sensor of claim 5 wherein the microcontroller transitions to the rest state when the threshold current is in a range of about less than 75 mA to about more than −100 mA for a predetermined time period.

8. The energy storage device sensor of claim 2 wherein an auxiliary display circuit is in data communication with the printed circuit board and is powered by the energy storage device configured as a chemical battery through a battery application-specific, integrated circuit controller and a powered data cable.

9. The energy storage device sensor of claim 2 wherein an auxiliary communication circuit is in data communication with the printed circuit board and is powered by the energy storage device configured as a chemical battery through a battery application-specific, integrated circuit controller and a powered data cable.

10. A battery sensor comprising:
a shunt defining a resistance area;
a printed circuit board in electrical communication with the resistance area through two spaced-apart electrical contacts that establish a resistance datum, the printed circuit board having a powered data connection and further including a microcontroller having a memory and a processor, the microcontroller including a data input to receive raw data from the shunt resistance area and a data output; and
a neural network model resident in the memory and configured with training data directed to a battery chemistry and including test-derived life cycle data, the neural network model configured to calculate and output at least one of a battery state of charge or a battery state of health.

11. The battery sensor of claim 10 wherein the shunt includes a first end attached to a first terminal connection of a battery and a second end connected to an external load, the battery comprising the battery chemistry configured as one of a lead-acid chemistry, a lithium-ion chemistry, a nickel metal hydride chemistry, or a nickel hydrogen chemistry.

12. The battery sensor of claim 10 wherein powered data connection is a powered data cable comprising at least one of a low voltage power supply, one or more communication lines for digital communications, or input/output wires configured to provide one of a sensor activation state from a rest position or an auxiliary device power switch.

13. The battery sensor of claim 12 wherein the powered data cable is the input/output wires configured as two wires, a first wire forming a ground connection and a second wire transmits one of a zero voltage signal defining an off state of an external device or a positive voltage state defining an on state the external device.

14. The battery sensor of claim 13 wherein the positive voltage defining the on state is between about one volt and about five volts; and the external device is one of an auxiliary display circuit, an auxiliary communication circuit, or a battery charger.

15. The battery sensor of claim 12 wherein the printed circuit board is in electrical communication with a powered data cable that comprises input/output wires configured to provide a sensor activation state from a rest state, the microcontroller is configured to move from the rest state to the activation state when the input/output wires transmit one of a charge event or a discharge event wherein a detected current on the shunt is greater than a threshold current value.

16. The battery sensor of claim 15 wherein when the input/output wires transmit the charge event, the threshold current value is above about 100 milliamperes, and wherein when the input/output wires transmit the discharge event, the threshold current value is below about −100 milliamperes.

17. The battery sensor of claim 15 wherein the microcontroller transitions to the rest state when the threshold current is in a range of about less than 75 mA to about more than −100 mA for a predetermined time period.

18. The battery sensor of claim 11 wherein an auxiliary display circuit is in data communication with the printed circuit board and is powered by the battery through a battery application-specific, integrated circuit controller and a powered data cable.

19. The battery sensor of claim 11 wherein an auxiliary communication circuit is in data communication with the printed circuit board and is powered by the battery through a battery application-specific, integrated circuit controller and a powered data cable.

20. The battery sensor of claim 10 wherein a polymer encapsulant is configured to provide an environmental seal over at least the printed circuit board.
